(19) United States
(12) Patent Application Publication
(10) Pub. No.: US 2025/0301582 A1
(43) Pub. Date: Sep. 25, 2025

(54) MOTOR CONTROLLER DEVICE

(71) Applicant: ADATA TECHNOLOGY CO., LTD., NEW TAIPEI CITY (TW)

(72) Inventors: CHIA-HSIANG HSIAO, New Taipei City (TW); Yi-Chen Lu, New Taipei City (TW)

(21) Appl. No.: 18/979,642

(22) Filed: Dec. 13, 2024

(30) Foreign Application Priority Data
Mar. 21, 2024 (TW) 113110461

(51) Int. Cl. H05K 5/02; B60R 16/03; H02G 5/02

(52) U.S. Cl. CPC H05K 5/0217; H02G 5/02; H05K 5/0247; B60R 16/03

(57) ABSTRACT

A motor controller device includes a controller body and an external container. The controller body has a surface, and the surface is provided with a plurality of contacts and a terminal slot. The external container is disposed on the controller body. The external container includes a plurality of conductive busbars. The plurality of conductive busbars are disposed on the surface and are respectively connected to the plurality of contacts. Two ends of the plurality of conductive busbars extend toward different sides of the surface.

### CROSS-REFERENCE TO RELATED PATENT APPLICATION

This application claims the benefit of priority to Taiwan Patent Application No. 113110461, filed on Mar. 21, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a controller device, and more particularly to a motor controller device.

### BACKGROUND OF THE DISCLOSURE

Existing motor controllers are designed with fixed wiring directions when being connected to multiple external wires. Generally, the motor controllers are designed to match specific vehicles. That is, a particular motor controller can only be installed in a specific vehicle. In other words, the wire arrangement on existing motor controllers is pre-designed to fit the internal space of the vehicle. As a result, a single controller cannot be used universally for different vehicles. The controller's casing often needs to be customized for the specific vehicle of different customers, leading to excessively high development costs for the casing molds.

If the controller is installed in the wrong vehicle, for example, with the wiring direction facing upwards while the vehicle's internal space requires the wiring to extend to the left, it will causes disorganization in the vehicle's wiring layout, leading to excessive bending and break of the wires, thereby affecting the arrangement of other components inside the vehicle.

Therefore, how to overcome the above-mentioned problem through an improvement in structural design has become an important issue to be addressed in the related art.

### SUMMARY OF THE DISCLOSURE

In response to the above-referenced technical inadequacy, the present disclosure provides a motor controller device.

In order to solve the above-mentioned problems, one of the technical aspects adopted by the present disclosure is to provide a motor controller device, which includes a controller body and an external container. The controller body has a surface, and the surface is provided with a plurality of contacts and a terminal slot. The external container is disposed on the controller body. The external container includes a plurality of conductive busbars, and the plurality of conductive busbars are disposed on the surface and are respectively connected to the plurality of contacts. Two ends of the plurality of conductive busbars extend toward different sides of the surface.

Therefore, in the motor controller device provided by the present disclosure, by virtue of “the external container including a plurality of conductive busbars, and the plurality of conductive busbars being disposed on the surface and being respectively connected to the plurality of contacts” and “two ends of the plurality of conductive busbars extending toward different sides of the surface of the controller body,” the external container is equipped with the conductive busbars, so that the wire arrangement of the motor controller device can be changed according to the design of the extension direction of the conductive busbars.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a motor controller device according to an embodiment of the present disclosure;

FIG. 2 is a schematic exploded view of the motor controller device according to the embodiment of the present disclosure;

FIG. 3 is a schematic view of conductive busbars positioning above a controller body according to the embodiment of the present disclosure;

FIG. 4 is a schematic view of the conductive busbars being disposed on an adapter box; and

FIG. 5 is another schematic view of the conductive busbars being disposed on the adapter box.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiment

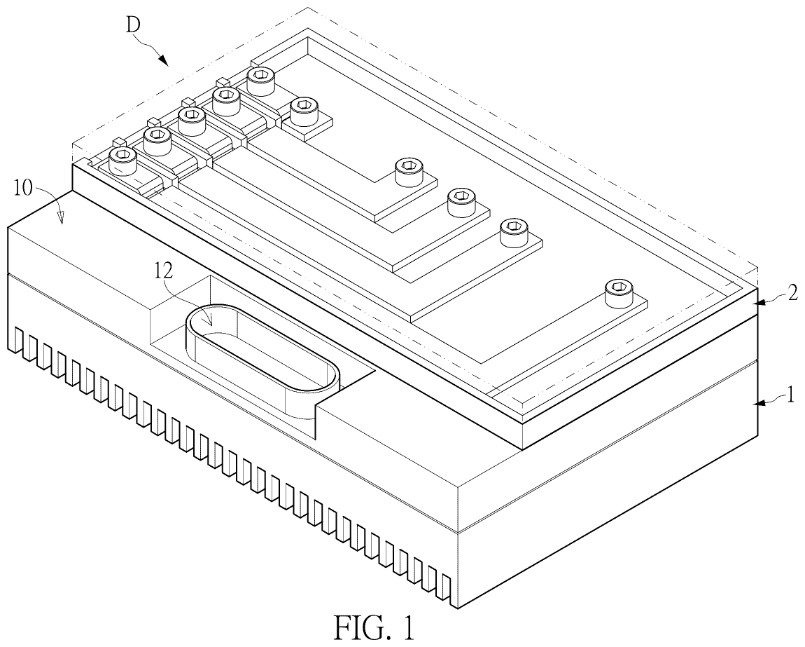

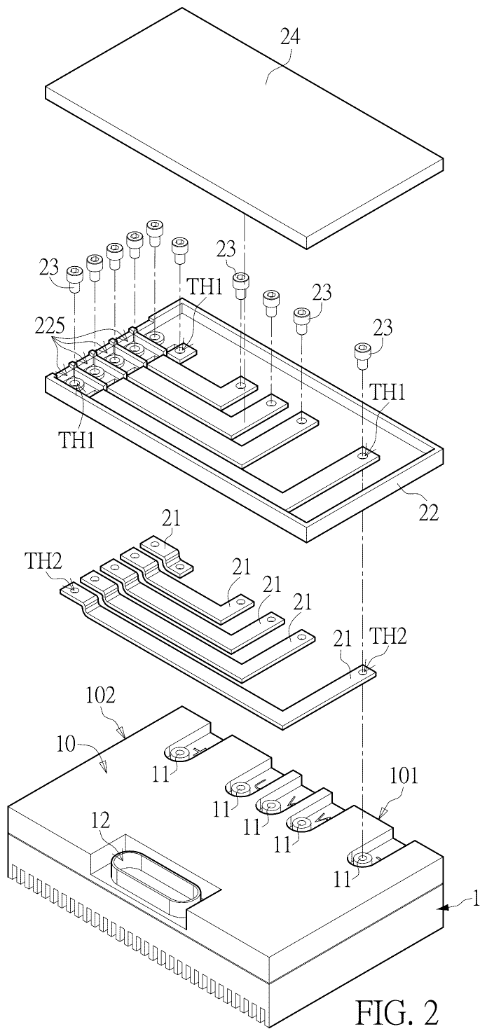

Reference is made to FIG. 1 and FIG. 2. FIG. 1 is a schematic view of a motor controller device according to an embodiment of the present disclosure. FIG. 2 is a schematic exploded view of the motor controller device according to the embodiment of the present disclosure. An embodiment of the present disclosure provides a motor controller device D, which includes a controller body 1 and an external container 2. The external container 2 is detachably disposed on the controller body 1. The controller body 1 has a surface 10. The surface 10 is provided with a plurality of contacts 11 and a terminal slot 12. The surface 10 has a first side 101 and a second side 102. The second side 102 is connected to a side of first side 101. The plurality of contacts 11 are adjacent to the first side 101 of the surface 10 and are arranged along the first side 101.

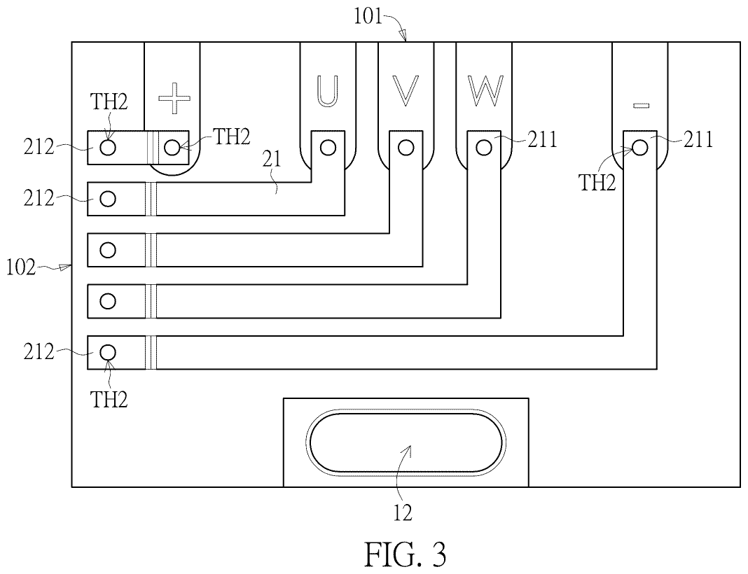

Reference is made to FIG. 1 to FIG. 3. FIG. 3 is a schematic view of conductive busbars positioning above a controller body according to the embodiment of the present disclosure. The external container 2 includes a plurality of conductive busbars 21. When the external container 2 is disposed on the controller body 1, the plurality of conductive busbars 21 are disposed on the surface 10 of the controller body 1. Two ends of the plurality of conductive busbars 21 extend toward different sides of the surface 10. Specifically, each of the conductive busbars 21 has a first end 211 and a second end 212. The first ends 211 of the plurality of conductive busbars 21 are connected to the plurality of contacts 11, respectively. The second ends 212 of the plurality of conductive busbars 21 are adjacent to the second side 102 of the surface 10 and are arranged along the second side 102. Through the arrangement of the conductive busbars 21, the plurality of contacts 11 on the controller body 1 that are close to the first side 101 can be adapted and extended to a position close to the first side 101. In other words, the conductive busbars 21 are mounted onto the controller body 1 through the configuration of the external container 2, and the wiring direction of the motor controller device D can be changed by designing the extension direction of the conductive copper bar 21. Therefore, when the motor controller device D is mounted in different vehicles, the design of the external box 2 can be modified according to the wiring space configuration within different vehicles, allowing the controller body 1 to remain fixed and unaffected by the internal space layout of the vehicle, thereby reducing the development costs of the controller device.

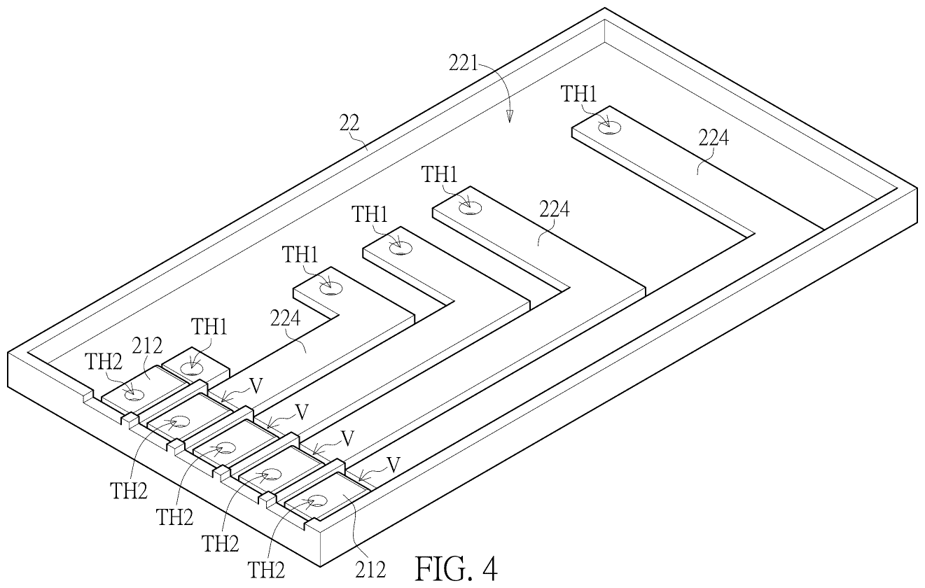

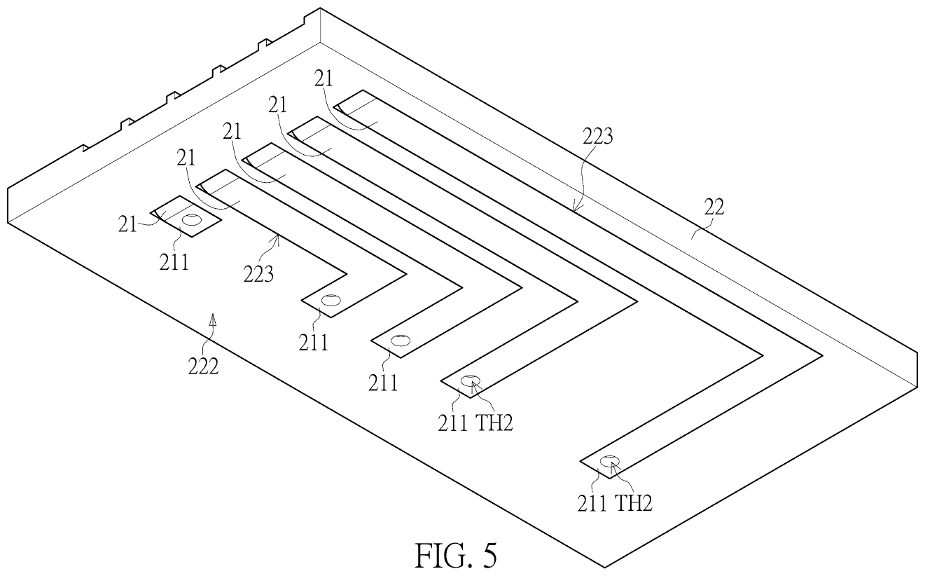

Reference is made to FIGS. 1, 2, 4, and 5. FIGS. 4 and 5 are schematic views of the conductive busbars being disposed on the adapter box. The external container 2 further includes an adapter box 22. The adapter box 22 has an upper surface 221 and a lower surface 222. The lower surface 222 includes a plurality of limiting grooves 223 that correspond to the plurality of conductive busbars 21, and the upper surface 221 includes a plurality of positioning protrusions 224 that are formed corresponding to positions of the plurality of limiting grooves 223. Shapes of the plurality of positioning protrusions 224 are the same as that of the plurality of conductive busbars 21.

The adapter box 22 includes a plurality of receiving grooves 225 on a side of the upper surface 221. The plurality of receiving grooves 225 are provided with a plurality of penetrating holes V therein, respectively. The adapter box 22 is disposed on the controller body 1 and covers the plurality of conductive busbars 21. Moreover, the plurality of conductive busbars 21 are respectively disposed in the plurality of limiting grooves 223 on the lower surface 222. The first ends 211 of the plurality of conductive busbars 21 are connected to the plurality of contacts 11, respectively. The second ends 212 of the plurality of conductive busbars 21 respectively pass through the plurality of penetrating holes V and extend to the upper surface 221, and are disposed in the plurality of receiving grooves 225 on the upper surface 221.

Since the adapter box 22 covers the plurality of conductive busbars 21, only the second ends 212 of the plurality of conductive busbars 21 are exposed from the adapter box 22. However, since the plurality of positioning protrusions 224 correspond to the plurality of conductive busbars 21, respectively, a user can identify the arrangement of the conductive busbars 21 through the shapes of the plurality of positioning protrusions 224, and further recognize the positions of the wiring terminals (i.e., the second ends 212) of the conductive busbars 21.

The adapter box 22 further includes a plurality of first through holes TH1, and the plurality of first through holes TH1 are located in the plurality of limiting grooves 223 and the plurality of receiving grooves 225. Each of the first through holes TH1 penetrates an upper surface and a lower surface of the adapter box 22. Each of the conductive busbars 21 is provided with two second through holes TH2. In each of the conductive busbars 21, one of the second through holes TH2 is located at the first end 211 of the conductive busbar 21, and another of the second through holes TH2 is located at the second end 212 of the conductive busbar 21. When the plurality of conductive busbars 21 are disposed in the adapter box 22, one of the second through holes TH2 of each of the conductive busbars 21 corresponds to one of the first through holes TH1 in one of the limiting grooves 223, and another of the second through holes TH2 of each of the conductive busbars 21 corresponds to one of the first through holes TH1 in one of the receiving grooves 225.

The external container 2 further includes a plurality of bolts 23. The plurality of bolts 23 respectively pass through the plurality of first through holes TH1 and the plurality of second through holes TH2, so as to fix the plurality of conductive busbars 21 on the controller body 1.

Reference is further made to FIGS. 1 and 2. The external container 2 further includes an upper cover 24. The upper cover 24 is used to cover the adapter box 22. The upper cover 24 is transparent or semi-transparent. The wiring direction of the motor controller device D can be confirmed by observing the positions of the wiring terminals (i.e., the second ends 212) of the conductive busbars 21 inside the upper cover 24. The user simply needs to open the upper cover 24 and securely connect external wires to the exposed second ends 212 of the conductive busbars 21 to be electrically connected to the contacts 11 on the controller body 1.

### Beneficial Effects of the Embodiment

In the motor controller device D provided by the present disclosure, by virtue of “the external container 2 including a plurality of conductive busbars 21, and the plurality of conductive busbars 21 being disposed on the surface 10 and being respectively connected to the plurality of contacts 11” and “two ends of the plurality of conductive busbars 21 extending toward different sides of the surface 10 of the controller body 1,” the external container 2 is equipped with the conductive busbars 21, so that the wire arrangement of the motor controller device can be changed according to the design of the extension direction of the conductive busbars 21.

Furthermore, the conductive busbars 21 are mounted onto the controller body 1 through the configuration of the external container 2, and the wiring direction of the motor controller device D can be changed by designing the extension direction of the conductive copper bar 21. Therefore, when the motor controller device D are mounted in different vehicles, the design of the external box 2 can be modified according to the wiring space configuration within each vehicle, which allows the controller body 1 to remain fixed and be unaffected by the internal space layout of the vehicle, thereby reducing the development costs of the controller device.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A motor controller device, comprising:
a controller body having a surface, wherein the surface is provided with a plurality of contacts and a terminal slot; and
an external container disposed on the controller body, wherein the external container includes a plurality of conductive busbars, the plurality of conductive busbars are disposed on the surface and are connected to the plurality of contacts, respectively, and two ends of the plurality of conductive busbars extend toward different sides of the surface.

2. The motor controller device according to claim 1, wherein the plurality of contacts are adjacent to a first side of the surface and are arranged along the first side, each of the conductive busbars has a first end and a second end, the first ends of the plurality of conductive busbars are connected to the plurality of contacts, respectively, and the second ends of the plurality of conductive busbars are adjacent to a second side of the surface and are arranged along the second side.

3. The motor controller device according to claim 2, wherein the external container further includes an adapter box, the adapter box has an upper surface and a lower surface, the lower surface includes a plurality of limiting grooves that correspond to the plurality of conductive busbars, and the upper surface includes a plurality of positioning protrusions that are formed corresponding to positions of the plurality of limiting grooves.

4. The motor controller device according to claim 3, wherein the adapter box includes a plurality of receiving grooves on a side of the upper surface, and the plurality of receiving grooves are provided with a plurality of penetrating holes therein, respectively; wherein the adapter box is disposed on the controller body and covers the plurality of conductive busbars, the plurality of conductive busbars are respectively disposed in the plurality of limiting grooves, and the second ends of the plurality of conductive busbars respectively pass through the plurality of penetrating holes and are disposed in the plurality of receiving grooves.

5. The motor controller device according to claim 4, wherein the adapter box further includes a plurality of first through holes, and the plurality of first through holes are located in the plurality of the limiting grooves and the plurality of the receiving grooves; wherein each of the conductive busbars has two second through holes, one of the second through holes of each of the conductive busbars is located at the first end of each of the conductive busbars, and another of the second through holes of each of the conductive busbars is located at the second end of each of the conductive busbars; wherein one of the second through holes of each of the conductive busbars corresponds to one of the first through holes of one of the limiting grooves, and another of the second through holes of each of the conductive busbars corresponds to one of the first through holes of one of the receiving grooves.

6. The motor controller device according to claim 5, wherein the external container further includes a plurality of bolts, the plurality of bolts respectively pass through the plurality of first through holes and the plurality of second through holes to fix the plurality of conductive busbars on the controller body.

7. The motor controller device according to claim 3, wherein the external container further includes an upper cover, and the upper cover is used to cover the adapter box.

8. The motor controller device according to claim 7, wherein the upper cover is transparent or semi-transparent.
